(19) United States
(12) Patent Application Publication
(10) Pub. No.: US 2015/0340422 A1
(43) Pub. Date: Nov. 26, 2015

(54) METHOD OF MANUFACTURING A MICRO-FABRICATED WAFER LEVEL INTEGRATED INDUCTOR OR TRANSFORMER FOR HIGH FREQUENCY SWITCH MODE POWER SUPPLIES

(71) Applicant: Texas Instruments Incorporated, Dallas, TX (US)

(72) Inventors: Dok Won Lee, Mountain View, CA (US); William D. French, San Jose, CA (US); Andrei Papou, San Jose, CA (US)

(21) Appl. No.: 14/286,562

(22) Filed: May 23, 2014

(51) Int. Cl. H01L 49/02; H01F 27/28; H01L 25/10; H01L 23/522; H01L 23/00

(52) U.S. Cl. CPC H01L 28/10; H01L 23/5226; H01L 24/33; H01L 25/105; H01L 24/17; H01L 24/03; H01L 24/80; H01F 27/2804; H01L 2224/30505; H01L 2924/01029; H01L 2924/06; H01L 2924/364; H01L 2224/1705; H01L 2225/1011; H01L 2224/80862; H01L 2224/0345; H01L 2224/80031; H01L 2224/03622; H01F 2027/2809

(57) ABSTRACT

A method of manufacturing an inductor on a wafer level process that can operate at 20 MHz with good efficiency and a high inductance density is disclosed, wherein the inductor design allows high frequency operation, low RDSON values and high efficiency.

### FIELD OF THE INVENTION

This invention relates to the field of integrated Inductors. More particularly, this invention relates to integrating inductors into wafer level integrated circuit process.

### BACKGROUND OF THE INVENTION

Inductors and transformers may be used in many different types of circuits. For example, they may be used for radio frequency (RF) circuits and high-frequency power distribution or conversion systems, such as a DC-DC voltage (or power) converter. Currently voltage converters may not he fully integrated on-chip for a variety of reasons. For example, a desired operating frequency may require an inductance value that is unobtainable based on the constrained physical size of the inductor. Further, in particular based on the effects of eddy currents, an on-chip inductor may not have a sufficiently high operating frequency for an RF or high-frequency voltage conversion application.

There are advantages to integrating a power system, for example including a DC-DC voltage converter, on the same die as the circuit(s) that is powered thereby. For example, as processor technology scales to smaller dimensions, supply voltages to circuits within a processor may also scale to smaller values. However, as the dimensions decrease, power consumption of the processor may increase. Using an off-die voltage converter to provide a small supply voltage to a processor with a large power consumption leads to a large total electrical current being supplied to the processor. This may increase the electrical current per pin, or the total number of pins required to power the processor as each pin has a maximum current handling capability. Also, an increase in supply current can lead to an increase in resistive as well as inductive voltage drop across various off-die and on-die interconnects, and to a higher cost for decoupling capacitors. Integrating the voltage converter onto the die may mitigate these and other problems.

All voltage regulators are built today with discrete inductors. The frequency of these regulators has been increasing over the last few years. increasing the frequency allows the required inductance to decrease. If the switching frequency is 20 MHz then the inductor required is ˜100 nH.

What is needed is a technique wherein an on chip inductor can be manufactured using wafer level processes and an inductor design that allows high frequency operation, low RDSON values and high efficiency.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the present application an integrated magnetic device, wherein the integrated magnetic device comprises: a silicon wafer substrate, an active region thereupon further comprising transistors, diodes, capacitors and resistors coupled by a conductive interconnect layer to form an active circuit, wherein the active region touches the top surface of the silicon wafer substrate and includes a first plurality of bond contacts, wherein the conductive interconnect layer is comprised of multiple layers of conductive material with insulating layer therebetween, the multiple layers of conductive material coupled together by a first plurality of vias piercing their associated insulating layer, wherein the top of the conductive interconnect layer is an insulating layer, having openings to expose a first plurality of bond contacts; a Silicon Nitride layer overlaying and touching the insulating layer, also having openings to expose the first plurality of bond contacts; a first layer of polymer deposited on top of the Silicon Nitride layer including a first plurality openings extending from the top of the first layer of polymer down to the first plurality of bond contacts; a first layer high conductance material, deposited on the top surface of the first layer of polymer, filling the first plurality of openings in the first polymer layer, forming the second plurality of vias, thereby coupling the first layer of high conductance material to the first plurality of bond contacts, wherein the first layer of high conductance material is configured to form a plurality of lower coil members and also includes a second plurality of bond contacts; a second layer of polymer, touching the ⁻first layer of polymer and the first layer of high conductance material, wherein the top surface of the second layer of polymer is planar, the second layer of polymer include a second plurality of openings extending from the top surface of the second layer of polymer down to the second plurality of bond contacts, wherein the second plurality of openings in the second layer of polymer are filled with a third plurality of vias; multiple layers of alternating magnetic film material and insulating material deposited and defined on the top surface of second layer of polymer, wherein the multiple layers of alternating magnetic film material and insulating material, as defined, do not touch the third plurality vias exposed on the top surface of the second layer of polymer; a third layer of polymer is deposited touching the second layer of polymer and the top of the multiple layers of alternating magnetic material and insulating material, the third layer of polymer includes a third plurality of openings extending from the top surface of the third layer of polymer down to the top surfaces of the third plurality of vias; a second layer high conductance material is deposited on the top surface of the third layer of polymer, wherein the second layer of high conductance material fills the third plurality of openings in the third polymer layer, forming a fourth plurality of vias, thereby coupling the second layer of high conductance material to the first plurality of bond contacts, the third layer of high conductance material is configured to form a plurality of upper coil members and also includes a third plurality of bond contacts; and a fourth layer of polymer is deposited touching the third layer of polymer and the top of the second layer high conductance material, wherein the fourth layer of polymer includes openings extending from the top surface of the fourth layer of polymer down to the top surfaces second layer high conductance material, the openings in the fourth layer of polymer are fined with solder bails, wherein the solder balls provide connection to outside circuitry.

In accordance with another embodiment of the present application a method of forming an integrated magnetic device, wherein the method of forming an integrated magnetic device, comprises: providing a conventionally formed integrated circuit water wherein bond contacts of each of the integrated circuits are exposed through openings in the insulating layer at the top of the conductive interconnect layer; depositing and defining a layer of silicon nitride over the wafer, wherein the silicon nitride layer touches the insulating layer at the top of the conductive interconnect layer and exposes the bond pads exposed through the openings in the insulating layer at the top of the conductive interconnect layer, by using a pattern and etch process, the bond contacts are exposed through openings in the silicon nitride layer; spinning and patterning a first layer of polymer onto the wafer chosen from the group of polymers SU8 or PI-2622; sputtering a first seed layer of Ti/Cu on the top surface of the first layer of polymer; spinning and patterning a photoresist layer on the first seed layer using standard photo lithography processes; electroplating a first layer of high conductance material on the surface of the photoresist and into the open areas defined by the photoresist, touching the first seed layer and defining a plurality of lower coil members which include a second plurality of contacts, filling the first plurality of openings in the first polymer layer, thereby coupling the first layer of high conductance material to the first plurality of bond contacts; stripping the photoresist layer, using standard photoresist stripping methods and dry etching the exposed first seed layer; spinning a second layer of polymer onto the wafer and baking it to cure the polymer layer; depositing a patterned hard mask on the wafer touching the top surface of the second polymer, wherein a second plurality of openings are etched into the second polymer layer extending from the top surface of the second polymer layer down to the second plurality of contacts; removing the hard mask; sputtering a second seed layer of Ti/Cu on the top surface of the first layer of polymer; spinning and patterning a photoresist layer on the second seed layer using standard photo lithography processes; electroplating a layer of high conductance material into the open areas defined by the photoresist, touching the second seed layer and defining a first plurality of vias, thereby coupling the first plurality of vias to the first plurality of bond contacts; stripping the photoresist layer, using standard photoresist stripping methods and dry etching the exposed second seed layer; sputtering a layer of titanium on the top surface of the second layer of polymer, touching the second layer of polymer and the tops of the first plurality of vias; depositing. a laminated magnetic core comprised of multiple layers of alternating magnetic film material and insulating material using a Veeco Nexus PVDi Tool, in a magnetic field, on the top surface of the layer of titanium, wherein the multiple layers of alternating magnetic material and insulating material are defined to not touch the first plurality of vias exposed on the top surface of the second layer of polymer; patterning and etching of the multiple layers of alternating magnetic material and insulating material and the titanium layer, using standard photo resist processes, the photoresist is then stripped using standard techniques; spinning a third layer of polymer onto the wafer and baking it to cure the polymer layer; depositing a patterned hard mask on the wafer touching the top surface of the third polymer layer, wherein a third plurality of openings are etched into the third polymer layer extending from the top surface of the third polymer layer down to the first plurality vias; removing the hard mask; sputtering a third seed layer of Ti/Cu on the top surface of the third layer of polymer; spinning and patterning a photoresist layer on the third seed layer using standard photo lithography processes; electroplating a second layer of high conductance material on the surface of the photoresist and into the open areas defined by the photoresist, touching the third seed layer and defining a plurality of upper coil members which include a second plurality of contacts, filling the third plurality of openings in the third polymer layer, thereby coupling the second layer of high conductance material to the first plurality of bond contacts; stripping the photoresist layer, using standard photoresist stripping methods and dry etching the exposed first seed layer; depositing a fourth layer of polymer, touching the third layer of polymer and the second layer of high conductance material, the fourth layer of polymer includes openings extending from the top surface of the fourth layer of polymer down through the fourth layer of polymer to the second layer of high conductance material; subjecting the magnetic layers to a second anneal (300-500C) in the presence of a magnetic field (0.1-IT), wherein the second anneal further defines the easy/hard axes; and forming solder bumps in the openings formed in the fourth layer of polymer, touching the second layer of high conductance material.

### DESCRIPTION OF THE VIEWS OF THE DRAWING

FIGS. 1-3 are illustrations of steps in the fabrication of the inductors formed according to embodiments.

FIG. 3AA is an illustration of section AA FIG. 3. according to embodiments.

FIG. 3BB is an illustration of section AA FIG. 3. according to embodiments.

In the drawings, like reference numerals are sometimes used to designate like structural elements. It should also be appreciated that the depictions in the figures are diagrammatic and not to scale.

### DETAILED DESCRIPT OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Embodiments of a laminated magnetic material for inductors in integrated circuits and the method of manufacture thereof will be described. Reference will now be made in detail to a description of these embodiments as illustrated in the drawings. While the embodiments will be described in connection with these drawings, there is no intent to limit thorn to drawings disclosed herein. On the contrary, the intent is to cover all alternatives, modifications, and equivalents within the spirit and scope of the described embodiments as defined by the accompanying claims. Simply stated, an embodiment is an inductor that may include a laminated material structure to decrease eddy currents therein that may limit the operation of the inductor at high frequency. The inductor of an embodiment may include a plurality of metal lines substantially or completely surrounding a magnetic material. The inductor of an embodiment may also include a laminated magnetic layer or layers that may further include higher resistance or insulator layers. The increased resistance of the laminated magnetic layers may reduce eddy currents within the inductor and subsequently improve the performance of the inductor at higher frequencies. An embodiment may employ electroplating, electro less plating or sputtering techniques to firm a layer or layers of magnetic material, and in particular those layers adjacent to insulator layers.

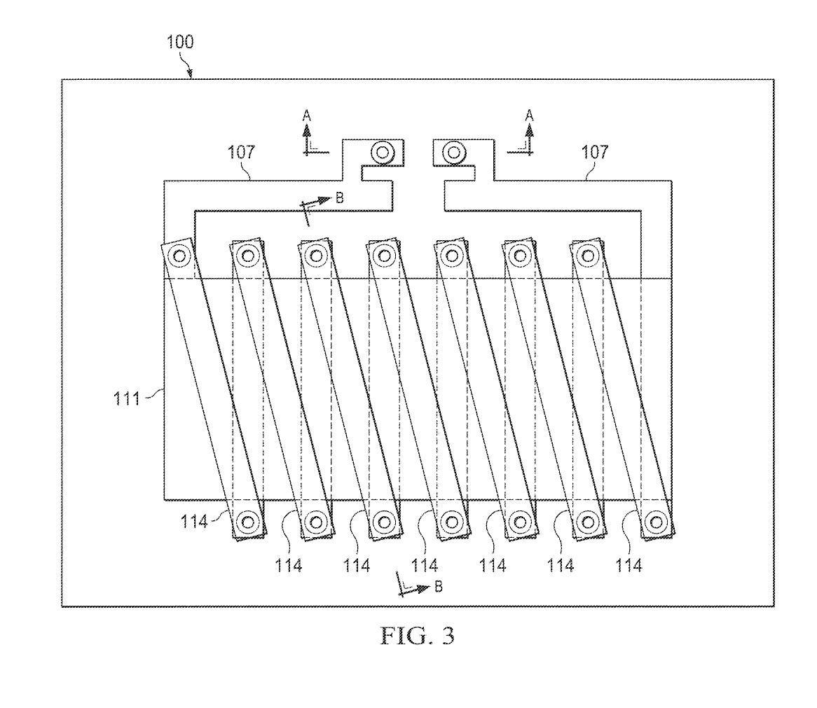

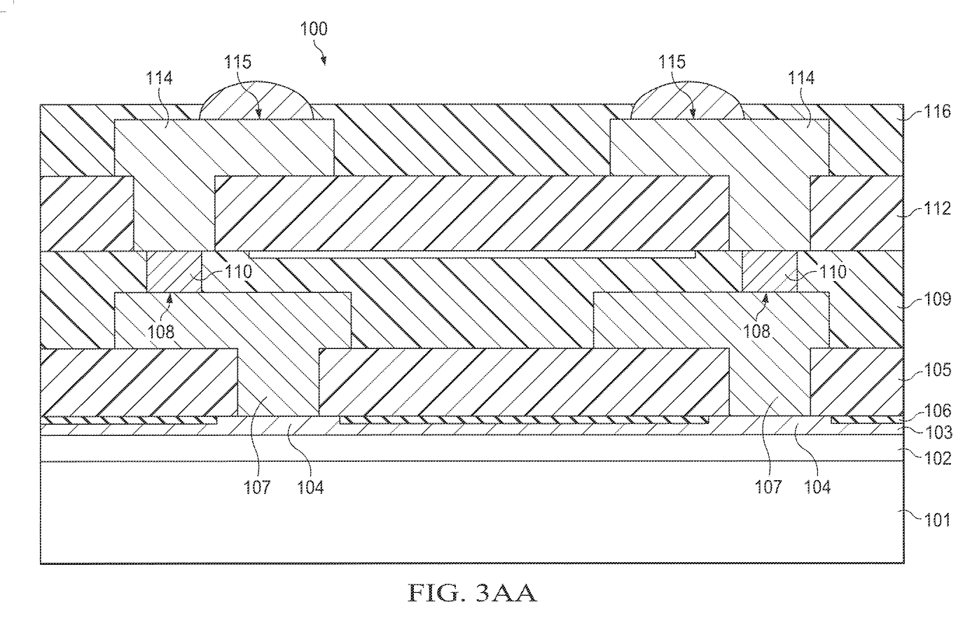

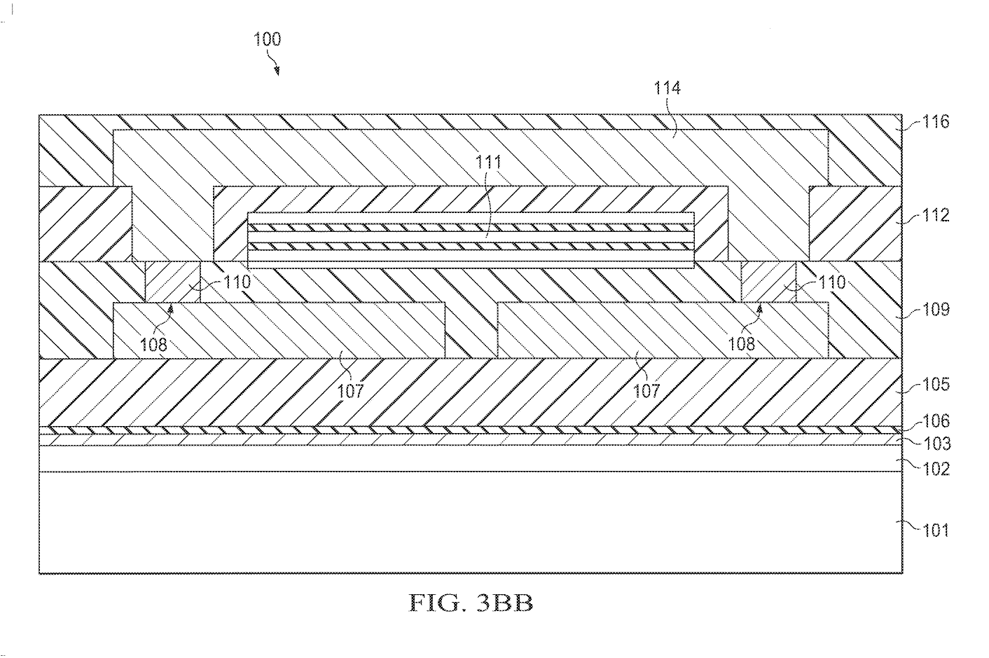

FIGS. 3AA and 3BB are cross sectional views of sections A-A and B-B of FIG. 3, respectively.

In an embodiment of the present invention 100, FIG. 3AA has a silicon wafer substrate 101. An active region 102 comprising transistors, diodes, capacitors and resistors coupled by a conductive interconnect layer 103 to form an active circuit, wherein the active region 102 touches the top surface of the silicon wafer substrate and includes a first plurality of bond contacts 104. The conductive interconnect layer 103 can be comprised of multiple layers of conductive material with insulating layer therebetween. The multiple layers of conductive material can be coupled together by a plurality of vias piercing their associated insulating layer, wherein the top of the conductive interconnect layer 103 is an insulating layer, having openings to expose a ⁻first plurality of bond contacts 104. Additionally the insulating layer on top of the conductive interconnect layer can be covered by a Silicon Nitride layer 106, having openings to expose the first plurality of bond contacts 104.

A first layer of polymer 105 can be deposited on top of the Silicon Nitride layer and also include a first plurality openings extending from the top of the first layer of polymer down to the first plurality of bond contacts 104. The first layer of polymer 105 can act as a stress relief layer between the inductor and the silicon wafer. It can he between 5 um-15 um in thickness. This can also act to reduce coupling between the copper windings and the silicon wafer substrate 101. The first layer of polymer can be chosen from the group of polymers SU8 PI-2622.

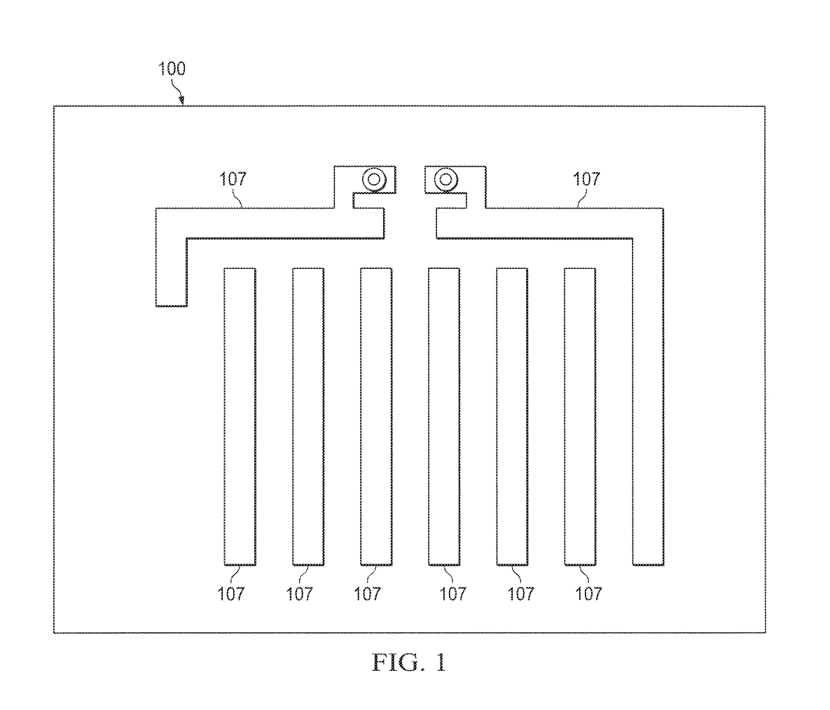

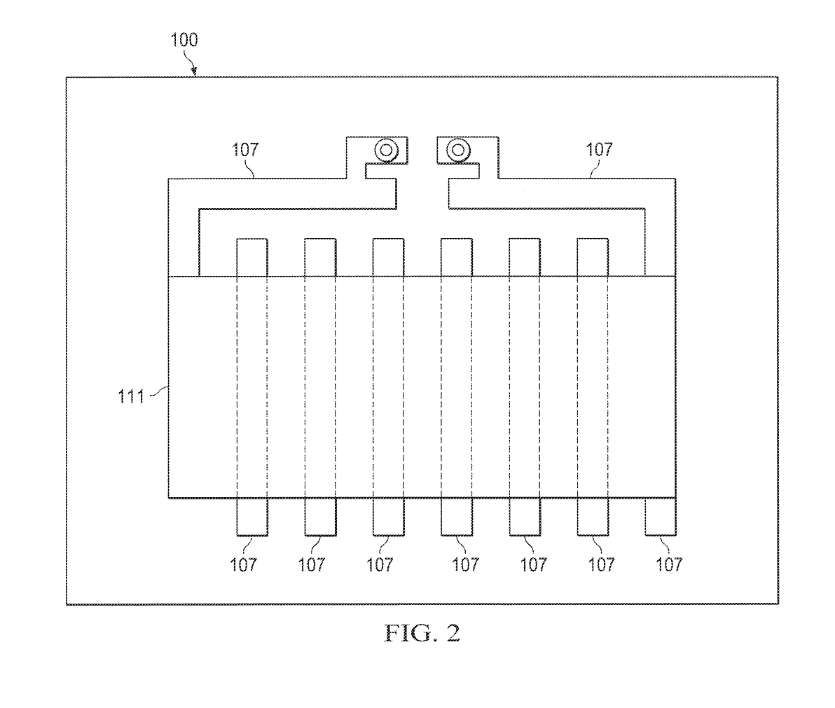

A first layer high conductance material 107 FIG. 1 can be deposited on the top surface of the first layer of polymer 105, filling the openings in the first polymer layer, thereby coupling the first layer of high conductance material 107 to the first plurality of bond contacts 104. The first layer of high conductance material 107 can also be configured to form a plurality of lower coil members and also includes a second plurality of bond contacts 108. The first layer of high conductance material 107 can be comprised of copper with a thickness of 20 μm.

A second layer of polymer 109, touching the first layer of polymer 105 and the first layer high conductance material 107 wherein the top surface of the second layer of polymer is planar. The second layer of polymer 109 can include openings extending from the top surface of the second layer of polymer 109 down to the second plurality of contacts 108. The openings in the second layer of polymer can be filled with a first plurality of vias 110. The first plurality of vias 110 can he copper. The second layer of polymer 109 can be chosen from the group of polymers SU8 3000 or PI-2622

Multiple layers of alternating magnetic material and insulating material 111 FIG. 2 can be deposited and defined on the top surface of second layer of polymer 109, wherein the multiple layers of alternating magnetic material and insulating material 111, as defined, do not touch the first plurality of vias 110 exposed on the top surface of the second layer of polymer 109.

Each magnetic film layer can have thickness ranges from 0.1 μm to 3 μm with a 10 nm AlN dielectric in between. The magnetic layers can be selected from the group of Ni80Fe20, Co90Ta5Zr5 or FeAlN. The laminated magnetic core total thickness can be between 5-15 μm

A third layer of polymer 112 can be deposited next, touching the second layer of polymer 109 and the top of the multiple layers of alternating magnetic material and insulating material 111. The third layer of polymer can include openings extending from the top surface of the third layer of polymer 112 down to the top surfaces of the first plurality of vias 110.

A second layer high conductance material 114 FIG. 3 can be deposited on the top surface of the third layer of polymer 112, wherein the second layer of high conductance material 114 fills the openings in the third polymer layer 112 thereby coupling the second layer of high conductance material 114 to the first plurality of bond contacts 104. The third layer of high conductance material 114 can also be configured to form a plurality of upper coil members and also includes a third plurality of bond contacts 115. The second layer of high conductance material 114 can be comprised of copper with a thickness of 20 μm.

A fourth layer of polymer 116 can be deposited next, touching the third layer of polymer 112 and the top of the second layer high conductance material 114. The fourth layer of polymer can include openings extending from the top surface of the fourth layer of polymer 112 down to the top surfaces second layer high conductance material 114. The openings in the fourth layer of polymer can be filled with solder balls 116, wherein the solder balls provide connection to outside circuitry.

In accordance with another embodiment of this invention, the wafer level integrated inductor is fabricated by providing a conventionally formed integrated circuit wafer 101, 102 and 103 wherein the bond contacts 104 of each of the integrated circuits are exposed through openings in the insulating layer at the top of the conductive interconnect layer 103.

A layer of silicon nitride is deposited over the wafer, touching the insulating layer at the top of the conductive interconnect layer 103 and the bond pads 104 exposed through the openings in the insulating layer at the top of the conductive interconnect layer 103. Using a pattern and etch process, the bond contacts 104 are exposed through openings in the silicon nitride layer,

A first layer of polymer 105, chosen from the group of polymers SU8 or PI-2622 is spun onto the wafer.

If the first layer of polymer 105 spun onto the wafer is PI-2622, it is then baked to cure the polymer layer. A patterned hard mask is deposited on the wafer touching the top surface of the first polymer 105. Openings are etched into the first polymer layer 105 extending from the top surface of the first polymer layer 105 down to the plurality of bond contacts 104. The first layer of polymer is configured to act as a stress relief layer between an inductor and the silicon wafer, wherein the thickness of the first layer of polymer is between 5 μm-15 μm. The hard mask is then removed.

If the first layer of polymer 105 spun onto the wafer is SU8, it is then soft baked. A photoresist layer is deposited and patterned, wherein an exposure by a light source takes place. Miler exposure, a post exposure bake is performed. The photoresist and the unexposed SU8 is then developed off, wherein the SU8 is then hard baked after developing. The SU8 exposed to the light source will remain on the wafer after the developing process.

A first seed layer of Ti/Cu is sputtered on the top surface of the first layer of polymer 105.

A photoresist layer is spun onto the wafer and patterned using standard photo lithography processes.

A first layer of high conductance material 107 is then electroplated onto the surface of the photoresist and into the open areas defined by the photoresist, touching the first seed layer on the first polymer layer 105 and defining a plurality of lower coil members 107 which include a second plurality of contacts 108, while filling the openings in the first polymer layer 105, thereby coupling the first layer of high conductance material to the first plurality of bond contacts 104. The first layer of high conductance material can he composed of 20 μm of copper. The photoresist layer is stripped using standard photo stripping methods and following the photoresist strip, the exposed first. seed layer is dry etched.

A second layer of polymer 109 is spun onto the wafer and baked to cure the polymer layer. A patterned hard mask is deposited on the wafer touching the top surface of the second polymer 109. Openings are etched into the second polymer layer 109 extending from the top surface of the second polymer layer 109 down to the plurality of bond contacts 108. The hard mask is then removed.

The second layer of polymer 109 can be chosen from the group of polymers SU8 3000 or PI-2622. If PI-2622 is used, a CMP process can be used to planarize the surface. If SU8 3000 is used instead of PI-2622 for the second Polymer layer 109, CMP is not required because SU8 3000 is largely self-planarizing to the required tolerance.

A second seed layer of Ti/Cu is sputtered can be sputtered on the top surface of the second layer of polymer 109 touching the second layer of polymer 109 and the tops of the second plurality of contacts 108.

A photoresist layer is spun onto the wafer and patterned using standard photo lithography processes.

A layer of high conductance material is then electroplated into the open areas defied by the photoresist, touching the second seed layer on the second polymer layer 109, filling the openings in the second polymer layer 109, defining a first plurality vias 110 thereby coupling the plurality of vias to the first plurality of bond contacts 104. The second layer of high conductance material can be composed of 20 μm of copper. The photoresist layer is stripped using standard photo stripping methods and following the photoresist strip, the exposed first seed layer is city etched.

A layer of titanium is sputtered on the top surface of the second layer of polymer, touching the second layer of polymer and the tops of the first plurality of vias 110;

A laminated magnetic core 111 comprised of multiple layers of alternating magnetic material and insulating material FIG. 2 can be deposited using a Veeco Nexus PVDi Tool in a magnetic field on the top surface of the layer of titanium, wherein the multiple layers of alternating magnetic material and insulating material 111 are defined to not touch the first plurality of vias 110 exposed on the top surface of the second layer of polymer 109.

Each magnetic film layer can be sputtered, with thickness ranges from 0.1 μm to 3 μm with a 10 nm AlN dielectric therebetween. Sputtering can be in the presence of a magnetic field to determine the easy axis of the magnetic material. The orientation is such that the B-field in the multiple layers of alternating magnetic material and insulating material 111 is in the direction of the hard axis. The magnetic layers can be selected from the group of Ni80Fe20, Co90Ta5Zr5 or FeAlN. The magnetic layers can be subjected to an anneal (300-500C) in the presence of a magnetic field after sputtering.

This acts to further define the easy/hard axes. The laminated magnetic core 111 total thickness can be between 5-15 μm

Standard photo resist process can he used to pattern and etch the laminated magnetic core 111. The Multiple layers of alternating magnetic material and insulating material and the Ti adhesion layer can then he etched. The photoresist is then stripped using standard techniques.

A third layer of polymer 112 is spun onto the wafer and baked to cure the polymer layer. A patterned hard mask is deposited on the wafer touching the top surface of the third polymer layer 112. Openings are etched into the third polymer layer 112 extending from the top surface of the third polymer layer 112 down to the first plurality of vias 110. The hard mask is then removed.

A third seed layer of Ti/Cu is sputtered can be sputtered on the top surface of the third layer of polymer 112 touching the third layer of polymer 112 and the tops of the first plurality of vias 110.

A photoresist layer is spun onto the wafer and patterned using standard photo lithography processes.

A second layer of high conductance material 114 is then electroplated onto the surface of the photoresist and into the open areas defied by the photoresist, touching the third seed layer on the third polymer layer 112 and defining a plurality of upper coil members 114 which include a second plurality of contacts 115, while filling the openings in the third polymer layer 112, thereby coupling the second layer of high conductance material to the first plurality of bond contacts 104. The second layer of high conductance material can be composed of 20 μm of copper. The photoresist layer is stripped using standard photo stripping methods and following the photoresist strip, the exposed first seed layer is dry etched.

A fourth layer of polymer 116 is spun onto the wafer and baked to cure the polymer layer. A patterned hard mask is deposited on the wafer touching the top surface of the fourth polymer layer 116. Openings are etched into the third polymer layer 116 extending from the top surface of the fourth polymer layer 116 down to the second plurality of contacts 115. The hard mask is then removed.

The magnetic layers can be subjected to a second anneal (300-500C) in the presence of a magnetic field (0.1-1T), This acts to further define the easy/hard axes,

Finally solder bumps are formed in the openings formed in the fourth layer of polymer 116 touching the third layer of high conductance material 114 thereby coupling to the first plurality of bond contacts 104.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. An integrated magnetic device, comprising:
a silicon wafer substrate, an active region thereupon further comprising transistors, diodes, capacitors and resistors coupled by a conductive interconnect layer to form an active circuit, wherein the active region touches the top surface of the silicon wafer substrate and includes a first plurality of bond contacts, wherein the conductive interconnect layer is comprised of multiple layers of conductive material with insulating layer therebetween, the multiple layers of conductive material coupled together by a first plurality of vias piercing their associated insulating layer, wherein the top of the conductive interconnect layer is an insulating layer, having openings to expose a first plurality of bond contacts;
a Silicon Nitride layer overlaying and touching the insulating layer, also having openings to expose the first plurality of bond contacts;
a first layer of polymer deposited on top of the Silicon Nitride layer including a first plurality openings extending from the top of the first layer of polymer down to the first plurality of bond contacts;
a first layer high conductance material, deposited on the top surface of the first layer of polymer, tilling the first plurality of openings in the first polymer layer, forming the second plurality of vias, thereby coupling the first layer of high conductance material to the first plurality of bond contacts, wherein the first layer of high conductance material is configured to form a plurality of lower coil members and also includes a second plurality of bond contacts;
a second layer of polymer, touching the first layer of polymer and the first layer of high conductance material, wherein the top surface of the second layer of polymer is planar, the second layer of polymer include a second plurality of openings extending from the top surface of the second layer of polymer down to the second plurality of bond contacts, wherein the second plurality of openings in the second layer of polymer are filled with a third plurality of vias;
multiple layers of alternating magnetic film material and insulating material deposited and defined on the top surface of second layer of polymer, wherein the multiple layers of alternating magnetic film material and insulating material, as defined, do not touch the third plurality of vias exposed on the top surface of the second layer of polymer;
a third layer of polymer is deposited touching the second layer of polymer and the top of the multiple layers of alternating magnetic material and insulating material, the third layer of polymer includes a third plurality of openings extending from the top surface of the third layer of polymer down to the top surfaces of the third plurality of vias;
a second layer high conductance material is deposited on the top surface of the third layer of polymer, wherein the second layer of high conductance material fills the third plurality of openings in the third polymer layer, forming a fourth plurality of vias, thereby coupling the second layer of high conductance material to the first plurality of bond contacts, the third layer of high conductance material is configured to form a plurality of upper coil members and also includes a third plurality of bond contacts; and
a fourth layer of polymer is deposited touching the third layer of polymer and the top of the second layer high conductance material, wherein the fourth layer of polymer includes openings extending from the top surface of the fourth layer of polymer down to the top surfaces second layer high conductance material, the openings in the fourth layer of polymer are filled with solder balls, wherein the solder balls provide connection to outside circuitry.

2. The integrated magnetic device of claim 1, wherein the first layer of polymer is configured to act as a stress relief layer between an inductor and the silicon wafer, wherein the thickness of the first layer of polymer is between 5 μm-15 μm, the first layer of polymer is chosen from the group of polymers SU8 or PI-2622.

3. The integrated magnetic device of claim 1, wherein he second layer of polymer is chosen from the group of polymers SU8 3000 or PI-2622.

4. The integrated magnetic device of claim I, wherein each magnetic film layer has a thickness that ranges from 0.1 μm to 3 μm with a 10 nm AlN dielectric in between, the composition of the magnetic film layers are selected from the group of Ni80Fe20, Co90Ta5Zr5 or FeAlN.

5. The integrated magnetic device of claim 1, wherein the laminated magnetic core total thickness is between 5-15 μm.

6. The integrated magnetic device of claim 1, wherein the first and second layers of high conductance material are comprised of copper with a thickness of 20 μm.

7. A method of forming an integrated magnetic device, comprising:
providing a conventionally formed integrated circuit wafer wherein bond contacts of each of the integrated circuits are exposed through openings in the insulating layer at the top of the conductive interconnect layer;
depositing and defining a layer of silicon nitride over the wafer, wherein the silicon nitride layer touches the insulating layer at the top of the conductive interconnect layer and exposes the bond pads exposed through the openings in the insulating layer at the top of the conductive interconnect layer, by using a pattern and etch process, the bond contacts are exposed through openings in the silicon nitride layer;
spinning and patterning a first layer of polymer onto the wafer chosen from group of polymers SU8 or PI-2622;
sputtering a first seed layer of Ti/Cu on the top surface of the first layer of polymer;
spinning and patterning a photoresist layer on the first seed layer using standard photo lithography processes;
electroplating a first layer of high conductance material on the surface of the photoresist and into the open areas defined by the photoresist, touching the first seed layer and defining a plurality of lower coil members which include a second plurality of contacts, filling the first plurality of openings in the first polymer layer, thereby coupling the first layer of high conductance material to the first plurality of bond contacts;
stripping the photoresist layer, using standard photoresist stripping methods and dry etching the exposed first seed layer;
spinning a second layer of polymer onto the wafer and baking it to cure the polymer layer;
depositing a patterned hard mask on the wafer touching the top surface of the second polymer, wherein a second plurality of openings are etched into the second polymer layer extending from the top surface of the second polymer layer down to the second plurality of contacts;
removing the hard mask;
sputtering a second seed layer of Ti/Cu on the top surface of the first layer of polymer;
spinning and patterning a photoresist layer on the second seed layer using standard photo lithography processes;
electroplating a layer of high conductance material into the open areas defined by the photoresist, touching the second seed layer and defining a first plurality of vias, thereby coupling the first plurality of vias to the first plurality of bond contacts;
stripping the photoresist layer, using standard photoresist stripping methods and dry etching the exposed second seed layer;
sputtering a layer of titanium on the top surface of the second layer of polymer, touching the second layer of polymer and the tops of the first plurality of vias;
depositing a laminated magnetic core comprised of multiple layers of alternating magnetic film material and insulating material using a Veeco Nexus PVDi Tool, in a magnetic field, on the top surface of the layer of titanium, wherein the multiple layers of alternating magnetic material and insulating material are defined to not touch the first plurality of vias exposed on the top surface of the second layer of polymer;
patterning and etching of the multiple layers of alternating magnetic material and insulating material and the titanium layer, using standard photo resist processes, the photoresist is then stripped using standard techniques;
spinning a third layer of polymer onto the wafer and baking it to cure the polymer layer;
depositing a patterned hard mask on the wafer touching the top surface of the third polymer layer, wherein a third plurality of openings are etched into the third polymer layer extending from the top surface of the third polymer layer down to the first plurality vias;
removing the hard mask;
sputtering a third seed layer of Ti/Cu on the top surface of the third layer of polymer;
spinning and patterning a photoresist layer on the third seed layer using standard photo lithography processes;
electroplating a second layer of high conductance material on the surface of the photoresist and into the open areas defined by the photoresist, touching the third seed layer and defining a plurality of upper coil members which include a second plurality of contacts, filling the third plurality of openings in the third polymer layer, thereby coupling the second layer of high conductance material to the first plurality of bond contacts;
stripping the photoresist layer, using standard photoresist stripping methods and dry etching the exposed first seed layer;
depositing a fourth layer of polymer, touching the third layer of polymer and the second layer of high conductance material, the fourth layer of polymer includes openings extending from the top surface of the fourth layer of polymer down through the fourth layer of polymer to the second layer of high conductance material;
subjecting the magnetic layers to a second anneal (300-500C) in the presence of a magnetic field (0.1-1T), wherein the second anneal further defines the easy/hard axes; and
forming solder bumps in the openings formed in the fourth layer of polymer, touching the second layer of high conductance material.

8. The method of forming an integrated magnetic device of claim 7, wherein the second layer of polymer is chosen from the group of polymers SU8 3000 or PI-2622, wherein if PI-2622 is chosen, a CMP process is used to planarize the surface, also wherein if SU8 3000 is used instead of PI-2622 for the second Polymer layer, CMP is not required because SU8 3000 is largely self-planarizing to the required tolerance.

9. The method of forming an integrated magnetic device of claim 7, wherein each magnetic film layer is sputtered, with thickness ranges from 0.1 μm to 3 μm with a 10 nm AlN dielectric therebetween, wherein the total laminated magnetic thickness is between 5-15 μm, the sputtering is accomplished in the presence of a magnetic field to determine the easy axis of the magnetic material, wherein the orientation is such that the B-field in the multiple layers of alternating magnetic material and insulating material is in the direction of the hard axis.

10. The method of forming an integrated magnetic device of claim 7, wherein the magnetic film layers can he selected from the group of Ni80Fe20, Co90Ta5Zr5 or FeAlN.

11. The method of forming an integrated magnetic device of claim 7, wherein the magnetic film layers are subjected to an anneal of 300-500° C., in the presence of a magnetic field after sputtering, further defining the easy/hard axes.

12. The method of forming an integrated magnetic device of claim 7, wherein the first and second layers of high conductance material are comprised of copper with a thickness of 20 μm.

13. The method of forming an integrated magnetic device of claim 7, wherein the first layer of polymer is configured to act as a stress relief layer between an inductor and the silicon wafer, wherein the thickness of the first layer of polymer is between 5 μm-15 μm, the first layer of polymer is chosen from the group of polymers SU8 or PI-2622.

14. The method of thrilling an integrated magnetic device of claim 7, wherein the first layer of polymer is PI-2622, and is then baked after spinning to cure the polymer layer, depositing a patterned hard mask on the wafer touching the top surface of the first polymer layer, wherein a first plurality of openings are etched into the first polymer layer extending from the top surface of the first polymer layer down to the plurality of bond contacts, removing the hard mask.

15. The method of forming an integrated magnetic device of claim 7, wherein the first layer of polymer is SU8, is then soft baked after spinning, depositing and patterning a photoresist layer on the wafer touching the top surface of the first polymer layer, wherein an exposure by a light source takes place, following the exposure, a post exposure bake is performed, wherein the photoresist and the unexposed SU8 is then developed off, wherein the SU8 is then hard baked after developing, the SU8 exposed to the light source will remain on the wafer after the developing process.
